(19) United States
(12) Patent Application Publication
(10) Pub. No.: US 2026/0309795 A1
(43) Pub. Date: Oct. 8, 2026

(54) BATTERY MANAGEMENT SYSTEM AND OPERATION METHOD THEREFOR

(71) Applicants: Hyundai Motor Company, Seoul (KR); Kia Corporation, Seoul (KR)

(72) Inventors: Beomgyu Kim, Hwaseong-Si (KR); Jonghu Yoon, Hwaseong-Si (KR); Jun Baek, Hwaseong-Si (KR)

(21) Appl. No.: 19/314,779

(22) Filed: Aug. 29, 2025

(30) Foreign Application Priority Data
Apr. 8, 2025 (KR) 10-2025-0045267

(51) Int. Cl. G01R 31/3842; G01R 31/396; H01M 10/48; H02J 7/56

(52) U.S. Cl. CPC G01R 31/3842; G01R 31/396; H01M 10/486; H02J 7/56

(57) ABSTRACT

A battery management system may include a plurality of cell monitoring units comprising at least one first type cell monitoring unit configured to directly wirelessly communicate with a battery management unit, at least one second type cell monitoring unit configured to relay wireless communication with the battery management unit, and at least one third type cell monitoring unit configured to wirelessly communicate with the battery management unit via relaying by the second type cell monitoring unit, and a control unit configured to control the plurality of cell monitoring units to reduce one or more of current consumption deviation or dark current deviation among the first type cell monitoring unit, the second type cell monitoring unit, and the third type cell monitoring unit.

### CROSS-REFERENCE TO RELATED APPLICATION

This present application claims the benefit of priority to Korean Patent Application No. 10-2025-0045267, filed on Apr. 8, 2025, in the Korean Intellectual Property Office, the entire disclosure of which is incorporated herein by reference.

### FIELD

The present disclosure relates to a battery management system and an operation method therefor, and more particularly, to a battery management system and an operation method therefor to which wireless communication technology is applied.

### BACKGROUND

A battery management system of an electric vehicle may transmit data via wireless communication between a battery management unit (BMU) and one or more cell monitoring units (CMUs). A signal strength of the wireless communication may be degraded due to structural limitations within the battery pack. To address this, a relay transmission function between CMUs may be applied. However, deviations in current consumption and/or dark current may occur for each CMU depending on whether relaying is performed.

For example, CMUs performing the relay function may have increased power consumption due to the continuous communication, while CMUs that are not relay targets may have relatively low power consumption. This may result in differences in current consumption and dark current for each CMU, causing imbalance in cell balancing, and may lead to battery life and/or performance degradation.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

Systems, apparatuses, and methods are described for a battery management system. A battery management system may comprise: monitoring circuitry comprising: at least one first type cell monitoring circuit configured to directly wirelessly communicate with a battery management circuit, at least one second type cell monitoring circuit configured to relay wireless communication with the battery management circuit, and at least one third type cell monitoring circuit configured to wirelessly communicate with the battery management circuit via relaying by the second type cell monitoring circuit; wherein the cell monitoring circuitry is configured to: receive, from a plurality of sensors, sensor data indicating one or more of a voltage, current, or temperature of a plurality of battery cells; and determine, based on the sensor data, status information of the plurality of battery cells; and a control circuit configured to: receive, from the cell monitoring circuitry via the at least one first type cell monitoring circuit or the at least one second type cell monitoring circuit, a plurality of wireless communications indicating the status information; and control, based on the status information, the cell monitoring circuitry to reduce one or more of: a current consumption deviation between the at least one first type cell monitoring circuit, the at least one second type cell monitoring circuit, and the at least one third type cell monitoring circuit; or a dark current deviation between the at least one first type cell monitoring circuit, the at least one second type cell monitoring circuit, and the at least one third type cell monitoring circuit.

One or more methods may be performed by a battery management system. A method performed by a battery management system may comprise: receiving, from cell monitoring circuitry associated with a battery comprising a plurality of battery cells, a plurality of wireless communications indicating status information of the plurality of battery cells, wherein the plurality of wireless communications comprises: at least one wireless communication, from at least one first type cell monitoring circuit of the cell monitoring circuitry, via direct wireless communication with a battery management circuit; at least one wireless communication, from at least one second type cell monitoring circuit of the cell monitoring circuitry, via relayed wireless communication with the battery management circuit; and at least one wireless communication, from at least one third type cell monitoring circuit among the cell monitoring circuitry, via relaying by the second type cell monitoring circuit to the battery management circuit; and controlling, based on the status information, the cell monitoring circuitry to reduce one or more of: a current consumption deviation between the at least one first type cell monitoring circuit, the at least one second type cell monitoring circuit, and the at least one third type cell monitoring circuit; or a dark current deviation between the at least one first type cell monitoring circuit, the at least one second type cell monitoring circuit, and the at least one third type cell monitoring circuit.

Also, or alternatively, an method for a battery management system may comprise: sending signals to configure: at least one first cell monitoring circuit, of a cell monitoring circuitry of a battery comprising a plurality of cells, to directly wirelessly communicate with a battery management circuit of the battery management system; at least one second cell monitoring circuit, of the cell monitoring circuitry, to relay wireless communications with the battery management circuit; and at least one third cell monitoring circuit, of the cell monitoring circuitry, to wirelessly communicate with the battery management circuit via relayed wireless communications from the at least one second cell monitoring circuit; receiving: via a direct wireless communication with the battery management circuit, first status information of a battery module associated with the at least one first cell monitoring circuit; via a relayed wireless communication with the battery management circuit, second status information of a battery module associated with the at least one second cell monitoring circuit; and via a wireless communication relayed by the at least one second cell monitoring circuit to the battery management circuit, third status information of a battery module associated with the at least one third cell monitoring circuit; and based on the first status information, second status information and third status information, controlling the cell monitoring circuitry to cause a reduction in one or more of: a current consumption deviation between the at least one first cell monitoring circuit, the at least one second cell monitoring circuit, and the at least one third cell monitoring circuit; or a dark current deviation between the at least one first cell monitoring circuit, the at least one second cell monitoring circuit, and the at least one third cell monitoring circuit.

These and other features and advantages are described in greater detail below.

### BRIEF DESCRIPTION OF THE DRAWINGS

The foregoing and other aspects, as well as the following detailed description of the examples, should be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a configuration diagram of a battery management system according to one example of the present disclosure.

FIG. 2 is a diagram showing a relationship between a plurality of cell monitoring units and a control unit according to one example of the present disclosure.

FIG. 3 is a flowchart illustrating an operation method for a battery management system according to one example of the present disclosure.

FIG. 4 is a diagram illustrating a battery module and a cell monitoring unit monitoring the battery module according to one example of the present disclosure.

FIG. 5 is a flowchart illustrating a control method for a battery management system according to one example of the present disclosure.

FIG. 6 shows an example computing system (e.g., a computing device of a vehicle or any other apparatus).

### DETAILED DESCRIPTION

Examples disclosed in the present specification will be described in greater detail with reference to the accompanying drawings. Throughout the accompanying drawings, the same reference numerals are used to designate the same or similar components and redundant descriptions thereof are omitted.

As used herein, the terms "module" and "unit" used to refer to components are used interchangeably in consideration of convenience of explanation, and thus, the terms per se should not be considered as having different meanings or functions. In describing the present disclosure, when the detailed description of relevant known technology is determined to unnecessarily obscure the gist of the present disclosure, the detailed description may be omitted. Furthermore, it should be understood that the appended drawings are intended only to help understand examples disclosed in the present document and do not limit the technical principles and scope of the present disclosure. Rather, it should be understood that the appended drawings include all of the modifications, equivalents or substitutes encompassed by the technical principles disclosed herein and belonging to the technical scope of the present disclosure.

Although the terms “first”, “second”, “third”, and the like may be used herein to describe various elements, components, regions, layers, and/or sections, these elements, components, regions, layers, and/or sections should not be limited by these terms. These terms are only used to distinguish one element from another.

If an element or layer is referred to as being "on," "engaged to," "connected to," or "coupled to" another element or layer, it may be directly on, engaged, connected, or coupled to the other element or layer (i.e., without any intervening elements or layers therebetween), and/or one or more intervening elements or layers may be present. In contrast, if an element is referred to as being "directly on," "directly engaged to," "directly connected to," or "directly coupled to" another element and/or layer, there may be no intervening elements or layers present between the element or layer and the other element and/or layer..

Unless otherwise defined, all technical and scientific terms used in the present disclosure have the same meanings as commonly understood by those skilled in the art of this application.

The terms "include," "comprise," “have,” and any variations thereof used in the specification of this application are intended to encompass non-exclusive inclusion.

For purposes of this application and the claims, using the exemplary phrase "at least one of: A; B; or C" or "at least one of A, B, or C," the phrase means "at least one A, or at least one B, or at least one C, or any combination of at least one A, at least one B, and at least one C. Further, exemplary phrases, such as "A, B, and C", "A, B, or C", "at least one of A, B, and C", "at least one of A, B, or C", etc., as used herein may mean each listed item or all possible combinations of the listed items. For example, "at least one of A or B" may refer to (1) at least one A; (2) at least one B; or (3) at least one A and at least one B. “One or more of” is synonymous with “at least one of” herein.

When a component, unit, device, element, apparatus, or the like of the present disclosure is described as having a purpose or performing an operation, function, or the like, the component, unit, device, element, apparatus, or the like should be considered herein as being “configured to” meet that purpose and/or to perform that operation or function. Each component, unit, device, element, apparatus, and the like may separately embody or be included with a processor and a memory, such as a non-transitory computer readable media, as part of the apparatus.

The term “unit” or “module” used in this specification signifies a unit or module that processes at least one function or operation, and may be realized by hardware, software, and/or a combination thereof. The operations of the method or the functions described in connection with the forms disclosed herein may be embodied directly in a hardware or a software module executed by a processor, or in a combination thereof.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

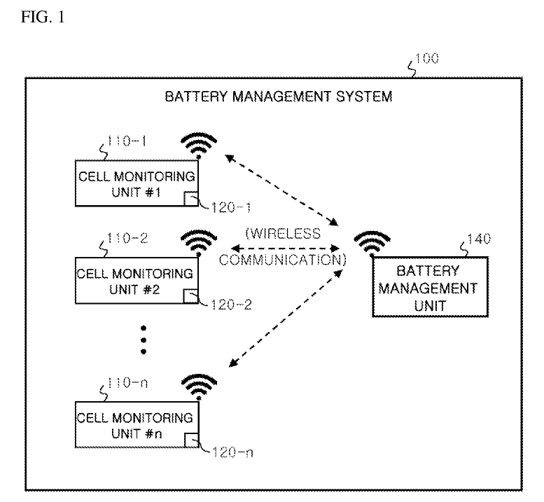

Hereinafter, a battery management system and an operation method therefor according to the present disclosure will be described in detail with reference to FIGS. 1 to 5. The present subject matter may solve various problems in some battery management systems by, for example, providing a mechanism that can effectively compensate for current deviations between CMUs, avoiding and/or reducing imbalances between CMUs that may degrade the stability and/or reliability of the battery in the long term.

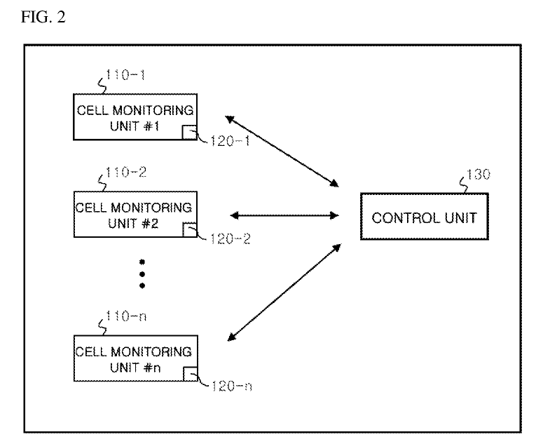

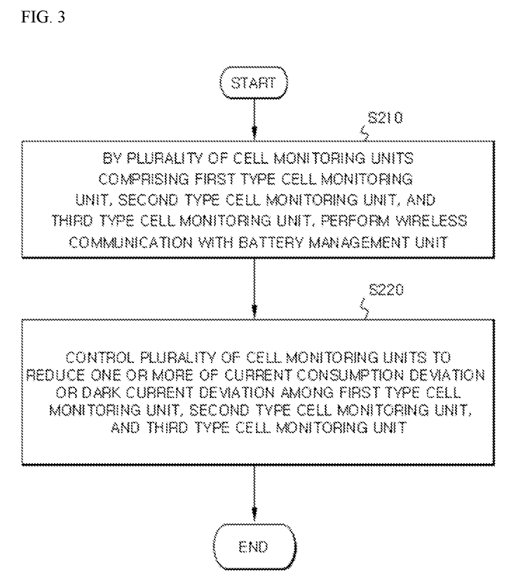

FIG. 1 is a configuration diagram of a battery management system according to one example of the present disclosure. FIG. 2 is a diagram showing a relationship between a plurality of cell monitoring units and a control unit according to one example of the present disclosure. FIG. 3 is a flowchart illustrating an operation method for a battery management system according to one example of the present disclosure.

Referring to FIGS. 1 and 2, a battery management system (100) according to an example of the present disclosure may include a plurality of cell monitoring units (110-1, 110-2, ..., 110-n) (e.g., cell monitoring circuits, cell monitors, cell monitoring devices), a plurality of balancing circuits (120-1, 120-2, ..., 120-n), a control unit (130) (e.g., a controller), and a battery management unit (140).

The plurality of cell monitoring units (110-1, 110-2, ..., 110-n) may perform wireless communication with the battery management unit (140) and may monitor corresponding battery modules (111) (see S210 in FIG. 3). The battery modules may each comprise a battery cell (e.g., of a battery comprising a cell stack) and/or a plurality of battery cells. The battery modules may be connected as part of a battery pack, for example.

For example, each of the plurality of cell monitoring units (110-1, 110-2, ..., 110-n) may be implemented as a CMU (cell monitoring unit). Each of the plurality of cell monitoring units (110-1, 110-2, ..., 110-n) may collect/determine status information of a corresponding battery module (e.g., in real time). Each of the plurality of cell monitoring units (110-1, 110-2, ..., 110-n) may transmit the status information (e.g., wirelessly) to the battery management unit (140). The battery management unit (140) may be implemented as a BMU (battery management unit). Each of the control unit (130), the plurality of cell monitoring units (110-1, 110-2, ..., 110-n) and the battery management unit (140) may be implemented in software, hardware or a combination of software and hardware. Each of the control unit (130), the plurality of cell monitoring units (110-1, 110-2, ..., 110-n) and the battery management unit (140) may be implemented and/or performed by one or more processors. For examples, each of the control unit (130), the plurality of cell monitoring units (110-1, 110-2, ..., 110-n) and the battery management unit (140) may include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. Each of the control unit (130), the plurality of cell monitoring units (110-1, 110-2, ..., 110-n) and the battery management unit (140) may also include software control module(s) implemented with a processor or logic circuitry for example. Each of the control unit (130), the plurality of cell monitoring units (110-1, 110-2, ..., 110-n) and the battery management unit (140) may include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. One or more storage type media may include any or all of the tangible memory of computers, processors, or the like, or associated modules thereof, such as various semiconductor memories, tape drives, disk drives and the like, which may provide non-transitory storage at any time for software programming.

The status information may comprise and/or be based on measurements of the corresponding battery modules, such as one or more cell voltages, temperature, and/or current. The cell monitoring units (110-1, 110-2, ..., 110-n) may measure/receive measurements of the voltage, current, and temperature of individual cells constituting the battery module. For example, each of the plurality of cell monitoring units (110-1, 110-2, ..., 110-n) may comprise and/or be communicatively connected to sensors (e.g., a voltage sensor, current sensor and/or temperature sensor) configured to measure the voltage, current and temperature of the individual cells. The plurality of cell monitoring units (110-1, 110-2, ..., 110-n) may, based on the measured voltage, current, and temperature, analyze/determine a balance state of the battery module (e.g., and detect overheating). The cell monitoring units (110-1, 110-2, ..., 110-n) may evaluate a state of charge (SOC) and/or state of health (SOH) of the battery modules to predict the current capacity and/or long-term performance degradation of the battery modules.

The plurality of cell monitoring units (110-1, 110-2, ..., 110-n) may comprise a first type cell monitoring unit that directly wirelessly communicates with the battery management unit (140), a second type cell monitoring unit that has a wireless communication relay function and may relay communication with the battery management unit (140), and a third type cell monitoring unit that may communicate with the battery management unit (140) via relaying by the second type cell monitoring unit.

For example, the signal strength of communication may gradually weaken as the distance between a cell monitoring unit (of 110-1, 110-2, ..., 110-n) and the battery management unit (140) increases. As the signal of the cell monitoring unit weakens, the probability of wireless communication failure increases, and wireless communication may become vulnerable to external interference signals. Therefore, relay transmission functions may be implemented in the wireless communication. Cell monitoring units (of 110-1, 110-2, ..., 110-n) located near the center (e.g., near the battery management unit (140) and/or between the farthest cell monitoring units and the closest cell monitoring units) may be utilized as relay nodes to compensate for the signal attenuation that occurs with increasing distance. The second type cell monitoring unit located near the center may secure communication stability by relaying signals between the third type cell monitoring unit, which may be those positioned at the greatest distance from the battery management unit (140), and the battery management unit (140), thereby enabling stable wireless communication for the distantly located cell monitoring units (of 110-1, 110-2, ..., 110-n).

Dark current deviation and current consumption deviation may occur between the first type cell monitoring unit, the second type cell monitoring unit, and the third type cell monitoring unit (e.g., due to differences in communication methods). For example, dark current may be measured as 0.095 mA for the first type cell monitoring unit, 0.12 mA for the second type cell monitoring unit, and 0.16m A for the third type cell monitoring unit, and current consumption may be measured as 1.99 mA for the first type cell monitoring unit, 2.26 mA for the second type cell monitoring unit, and 2.1 mA for the third type cell monitoring unit.

Therefore, to reduce dark current deviation and/or current consumption deviation between cell monitoring unit types, each of the plurality of cell monitoring units (110-1, 110-2, ..., 110-n) may include balancing circuits (120-1, 120-2, ..., 120-n) that perform active balancing and latch balancing.

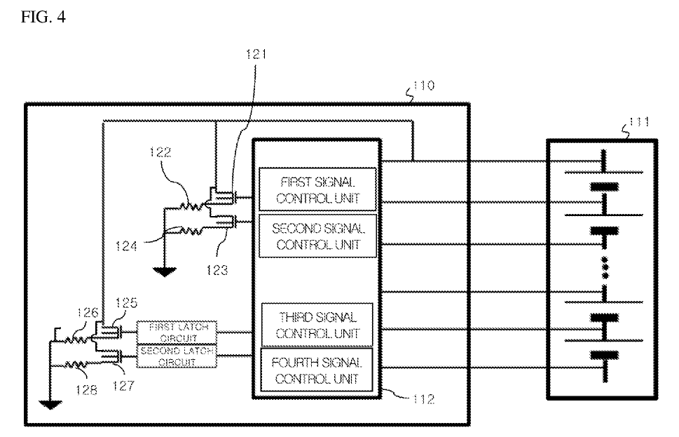

FIG. 4 is a diagram illustrating a cell monitoring unit according to one example of the present disclosure.

Referring to FIG. 4, each of the plurality of cell monitoring units (110-1, 110-2, ..., 110-n) may include a sensing unit (112) (e.g., comprising one or more sensors, such as a voltage sensor, temperature sensor, current sensor, etc.) for measuring information of a corresponding battery module (111) to enable monitoring. A wireless communication unit that performs wireless communication may be included in the sensing unit (112), and/or may be located within each cell monitoring unit as a separate module (e.g., comprising a receiver and/or transceiver in communication with the sensing unit (112). The sensing unit (112) may be provided with a first signal control unit, a second signal control unit, a third signal control unit, and/or a fourth signal control unit, which may be implemented as a general purpose input/output (GPIO). A first (121) (e.g., a first switch, such as a field effect transistor (FET)) may connect and/or disconnect the battery module (111) and a first discharge resistor (122) according to/based on a control signal of the first signal control unit (e.g., a first control signal from the sensor unit/sensor). A second switching unit (123) (e.g., a second switch, such as a FET) may connect and/or disconnect the battery module (111) and a second discharge resistor (124) according to/based on a control signal of the second signal control unit (e.g., a second control signal from the sensor unit/sensor). A third switching unit (125) (e.g., a third switch, such as a FET) may connect and/or disconnect the battery module (111) and a third discharge resistor (126) according to/based on a control signal of the third signal control unit connected to a first latch circuit (e.g., a third control signal from the sensor unit/sensor via the first latch circuit). A fourth switching unit (127) (e.g., a fourth switch, such as a FET) may connect and/or disconnect the battery module (111) and a fourth discharge resistor (128) according to/based on a control signal of the fourth signal control unit connected to a second latch circuit (e.g., a fourth control signal from the sensor unit/sensor via the first latch circuit).

The control unit (130) may control the first signal control unit, the second signal control unit, the third signal control unit, and the fourth signal control unit of each of the plurality of balancing circuits (120-1, 120-2, ..., 120-n) to cause performance of active balancing to reduce current consumption deviation between cell monitoring unit types and latch balancing to reduce dark current deviation between cell monitoring unit types (see S220 in FIG. 3).

The control unit (130) may be implemented as a BMU, and/or may also be formed as a part of the BMU. Also, or alternatively, the control unit (130) may be configured as a module of a battery management system (BMS), and/or may also be formed as a separate module independent from the BMS and/or in communication with the BMS. Furthermore, the control unit (130) may be implemented as hardware, software, or a combination thereof and/or may be implemented as firmware. The control unit (130) may be connected to each of the plurality of cell monitoring units (110-1, 110-2, ..., 110-n), by wire and/or wirelessly, to transmit and receive data and may be configured to control a state of the battery based on the transmitted and/or received data.

The third type cell monitoring unit may exhibit/experience the highest dark current. The third type cell monitoring unit may not perform latch balancing separately/independently, and only the first type cell monitoring unit and the second type cell monitoring unit may perform latch balancing. Since the second type cell monitoring unit exhibits the highest current consumption, the second type cell monitoring unit may not perform active balancing separately/independently, and only the first type cell monitoring unit and the third type cell monitoring unit may perform active balancing.

Specifically, the control unit (130) may, for the first type cell monitoring unit, connect the second switching unit to cause performance of the active balancing and connect the fourth switching unit to cause performance of the latch balancing, for the second type cell monitoring unit, connect the third switching unit to cause performance of the latch balancing, and for the third type cell monitoring unit, connect the first switching unit to cause performance of the active balancing.

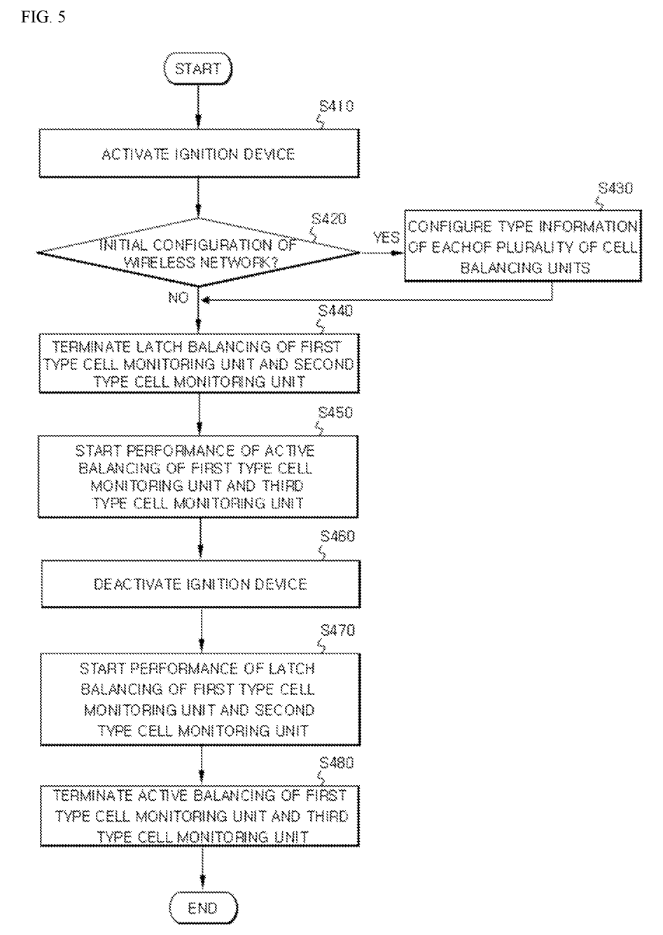

FIG. 5 is a flowchart illustrating a control method for a battery management system according to one example of the present disclosure. For convenience, FIG. 5 is described by way of an example in which the steps are performed by a processor circuit. One, some, or all steps of the example method of FIG. 5, or portions thereof, may be performed by one or more other circuits. One or some, steps of the example method of FIG. 5 may be omitted, performed in other orders, and/or otherwise modified, and/or one or more additional steps may be added.

Referring to FIG. 5, based on an ignition device (e.g., of a vehicle) being activated (S410), the control unit (130) may check whether a wireless network is to be initially configured(S420). If the wireless device is to be initially configured (e.g., has not yet been configured/is not configured/cell monitoring units are not yet assigned types/etc.) (S420 - Yes), type information (e.g., first type, second type, third type disclosed herein) of each of the plurality of cell monitoring units may be configured (e.g., assigned to each cell monitoring unit of the plurality) (S430). The type of balancing unit may be fixed/determined according/based on to location of the corresponding cell monitoring unit. The wireless network may be configured accordingly (e.g., based on the configured type information of the plurality of cell monitoring units). If the wireless network in configured (S420 - No; S430), the control unit (130) may cause termination of the latch balancing of the first type cell monitoring unit(s) and the second type cell monitoring unit(s) (S440). The control unit (130) may cause performance of the active balancing of the first type cell monitoring unit(s) and the third type cell monitoring unit(s) (S450). Based on the ignition device being deactivated (S460), the control unit (130) may start performance of latch balancing of the first type cell monitoring unit(s) and the second type cell monitoring unit(s) (S470). The control unit (130) may cause termination of the active balancing of the first type cell monitoring unit(s) and the third type cell monitoring unit(s) (S480).

The present disclosure is directed to providing a battery management system and an operation method therefor capable of addressing signal attenuation issues occurring in wireless communication between a battery management unit (BMU) and cell monitoring units (CMUs) in the battery management system, and utilizing a relay transmission function between CMUs to achieve stable data transmission.

The present disclosure is further directed to providing a battery management system and an operation method therefor capable of maintaining cell balancing uniformly by reducing differences in current consumption and dark current between CMUs performing the relay transmission function and CMUs not performing the relay transmission function.

The present disclosure is further directed to providing a battery management system and an operation method therefor capable of reducing current deviations within the battery management system and preventing battery life and performance degradation by classifying CMU roles in a fixed manner and applying fixed balancing circuits that compensate for dark current and current consumption by role.

Aspects of the present disclosure are not limited to those mentioned above, and other aspects and advantages not mentioned above will be understood from the following description, and become more apparent from the examples. Moreover, aspects of the present disclosure may be realized by the means and combinations thereof indicated in claims.

A battery management system according to one aspect of the present disclosure may include a plurality of cell monitoring units comprising at least one first type cell monitoring unit configured to directly wirelessly communicate with a battery management unit, at least one second type cell monitoring unit configured to relay wireless communication with the battery management unit, and at least one third type cell monitoring unit configured to wirelessly communicate with the battery management unit via relaying by the second type cell monitoring unit, and a control unit configured to control the plurality of cell monitoring units to reduce one or more of current consumption deviation or dark current deviation among the first type cell monitoring unit, the second type cell monitoring unit, and the third type cell monitoring unit.

Each of the plurality of cell monitoring units may include a plurality of balancing circuits configured to perform one or more of active balancing or latch balancing.

Further, an operation method for a battery management system according to another aspect of the present disclosure may include, by at least one first type cell monitoring unit among a plurality of cell monitoring units, directly wirelessly communicating with a battery management unit, by at least one second type cell monitoring unit among the plurality of cell monitoring units, relaying wireless communication with the battery management unit, and by at least one third type cell monitoring unit among the plurality of cell monitoring units, wirelessly communicating with the battery management unit via relaying by the second type cell monitoring unit, and by a control unit, controlling the plurality of cell monitoring units to reduce one or more of current consumption deviation or dark current deviation among the first type cell monitoring unit, the second type cell monitoring unit, and the third type cell monitoring unit.

Each of the plurality of cell monitoring units may include a plurality of balancing circuits configured to perform one or more of active balancing or latch balancing.

According to examples of the present disclosure, the battery management system may address signal attenuation issues that may occur in wireless communication between a battery management unit and cell monitoring units, and enable stable data transmission by utilizing the relay transmission function between cell monitoring units.

Further, according to examples of the present disclosure, the battery management system may maintain cell balancing uniformly by reducing differences in current consumption and dark current between CMUs performing the relay transmission function and CMUs not performing the relay transmission function.

Further, according to examples of the present disclosure, the battery management system may reduce current deviations within the battery management system and prevent battery life and performance degradation by classifying CMU roles in a fixed manner and applying fixed balancing circuits that compensate for dark current and current consumption by role.

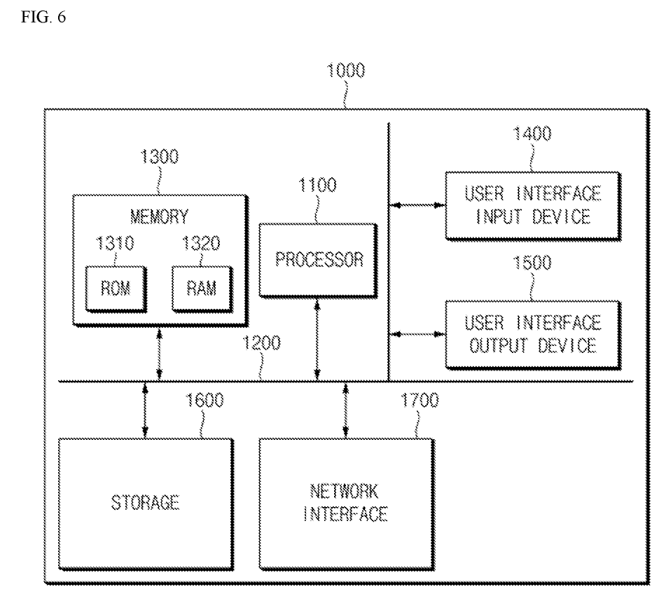

FIG. 6 shows an example computing system (e.g., a computing device of a vehicle or any other apparatus). One or more controllers, processors, etc. described herein, such as one or more components of the vehicle described herein or any other components and devices disclosed herein, may be implemented by or in the computing system as shown in FIG. 6.

A computing system 1000 may include at least one processor 1100, memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read-only memory (ROM) and a random-access memory (RAM).

Communication interface(s) (also referred to as communication device(s), communicator(s), communication module(s), communication unit(s), etc.), such as the network interface 1700, may allow software and/or data to be transferred between a device and one or more external devices, and/or between one or more components of a device. Communication interface(s) may include a receiver, a transmitter, a transceiver, a modem, a network interface and/or adapter (such as an Ethernet adapter), a radio transceiver, an antenna, a communication port, a Personal Computer Memory Card International Association (PCMCIA) slot and card, or the like. Software and data transferred via communication interface(s) may be in the form of signals, which may be electronic, electromagnetic, optical, infrared, or other signals capable of being received by communication interface(s). These signals may be provided to communication interface(s) via a communication path of a device, which may be implemented using, for example, wire or cable, fiber optics, a cellular link, a radio frequency (RF) link and/or other communications channels. Communication interface(s) may communicate using one or more communication protocols, such as Ethernet, Wi-Fi, near-field communication (NFC), Infrared Data Association (IrDA), Bluetooth, Bluetooth low energy (BLE), Zigbee, Long-Term Evolution (LTE), 5G New Radio (NR), vehicle-to-everything (V2X), a controller area network (CAN), or a local interconnect network (LIN), etc.

Accordingly, the operations of the method or algorithm described in connection with example example(s) disclosed in the specification may be directly implemented with a hardware module, a software module, or a combination of the hardware module and the software module, which is executed by the processor 1100. The software module may reside on a storage medium (e.g., the memory 1300 and/or the storage 1600) such as RAM, a flash memory, ROM, an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

As used in the present disclosure (especially in the appended claims), the terms "a/an" and "the" include both singular and plural referents, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof ("for example", "such as") are merely to describe the present disclosure in greater detail. Therefore, it should be understood that the scope of the present disclosure is not limited to the example examples described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example examples described above, and rather intended to include the following appended claims, and all modifications, equivalents, and alternatives falling within the spirit and scope of the following claims.

1. A battery management system comprising:
cell monitoring circuitry comprising:
at least one first type cell monitoring circuit configured to directly wirelessly communicate with a battery management circuit,
at least one second type cell monitoring circuit configured to relay wireless communication with the battery management circuit, and
at least one third type cell monitoring circuit configured to wirelessly communicate with the battery management circuit via relaying by the second type cell monitoring circuit;
wherein the cell monitoring circuitry is configured to:
receive, from a plurality of sensors, sensor data indicating one or more of a voltage, current, or temperature of a plurality of battery cells; and
determine, based on the sensor data, status information of the plurality of battery cells; and
a control circuit configured to:
receive, from the cell monitoring circuitry via the at least one first type cell monitoring circuit or the at least one second type cell monitoring circuit, a plurality of wireless communications indicating the status information; and
control, based on the status information, the cell monitoring circuitry to reduce one or more of:
a current consumption deviation between the at least one first type cell monitoring circuit, the at least one second type cell monitoring circuit, and the at least one third type cell monitoring circuit; or
a dark current deviation between the at least one first type cell monitoring circuit, the at least one second type cell monitoring circuit, and the at least one third type cell monitoring circuit.

2. The battery management system of claim 1, wherein each cell monitoring circuit of the cell monitoring circuitry comprises one or more balancing circuits configured to perform one or more of active balancing or latch balancing.

3. The battery management system of claim 2,
wherein each cell monitoring circuit of the cell monitoring circuitry further comprises a sensor, of the plurality of sensors, configured to measure information of a corresponding battery module comprising one or more battery cells, and
wherein, for each cell monitoring circuit, the one or more balancing circuits comprise:
a first switch configured to, based on a first control signal from the sensor, connect or disconnect the corresponding battery module and a first discharge resistor;
a second switch configured to, based on a second control signal from the sensor, connect or disconnect the corresponding battery module and a second discharge resistor;
a third switch configured to, based on a third control signal from the sensor, connect or disconnect via a first latch circuit the corresponding battery module and a third discharge resistor; and
a fourth switch configured to, based on a fourth control signal from the sensor, connect or disconnect via a second latch circuit to the corresponding battery module and a fourth discharge resistor,
wherein the control circuit is configured to control the sensor to send the first control signal, the second control signal, the third control signal, and the fourth control signal.

4. The battery management system of claim 3, wherein the control circuit is configured to:
for the at least one first type cell monitoring circuit, connect the second switch to cause the active balancing and connect the fourth switch to cause the latch balancing;
for the at least one second type cell monitoring circuit, connect the third switch to cause the latch balancing; and
for the at least one third type cell monitoring circuit, connect the first switch to cause the active balancing.

5. The battery management system of claim 2, wherein the control circuit is configured to, based on an ignition device being activated, cause termination of latch balancing for the at least one first type cell monitoring circuit and the at least one second type cell monitoring circuit.

6. The battery management system of claim 2, wherein the control circuit is configured to, based on an ignition device being activated, cause active balancing for the at least one first type cell monitoring circuit and the at least one third type cell monitoring circuit.

7. The battery management system of claim 2, wherein the control circuit is configured to, based on an ignition device being deactivated, cause latch balancing for the at least one first type cell monitoring circuit and the at least one second type cell monitoring circuit.

8. The battery management system of claim 2, wherein the control circuit is configured to, based on an ignition device being activated, cause termination of active balancing for the at least one first type cell monitoring circuit and the at least one third type cell monitoring circuit.

9. A method performed by a battery management system, the method comprising:
receiving, from cell monitoring circuitry associated with a battery comprising a plurality of battery cells, a plurality of wireless communications indicating status information of the plurality of battery cells, wherein the plurality of wireless communications comprises:
at least one wireless communication, from at least one first type cell monitoring circuit of the cell monitoring circuitry, via direct wireless communication with a battery management circuit;
at least one wireless communication, from at least one second type cell monitoring circuit of the cell monitoring circuitry, via relayed wireless communication with the battery management circuit; and
at least one wireless communication, from at least one third type cell monitoring circuit among the cell monitoring circuitry, via relaying by the second type cell monitoring circuit to the battery management circuit; and
controlling, based on the status information, the cell monitoring circuitry to reduce one or more of:
a current consumption deviation between the at least one first type cell monitoring circuit, the at least one second type cell monitoring circuit, and the at least one third type cell monitoring circuit; or
a dark current deviation between the at least one first type cell monitoring circuit, the at least one second type cell monitoring circuit, and the at least one third type cell monitoring circuit.

10. The method of claim 9, wherein each cell monitoring circuit of the cell monitoring circuitry comprises one or more balancing circuits configured to perform one or more of active balancing or latch balancing.

11. The method of claim 10, wherein the controlling of the cell monitoring circuitry comprises controlling of the cell a sensor, of a cell monitoring circuit of the cell monitoring circuitry, to send one or more of:
a first control signal configured to cause a first switch to connect or disconnect a first discharge resistor and a battery module corresponding to the cell monitoring circuit;
a second control signal configured to cause a second switch to connect or disconnect a second discharge resistor and the corresponding battery module;
a third control signal configured to cause a third switch to connect or disconnect a third discharge resistor and the corresponding battery module via a first latch circuit; and
a fourth control signal configured to cause a fourth switch to connect or disconnect a fourth discharge resistor and the corresponding battery module via a second latch circuit.

12. The method of claim 11, wherein the controlling of the cell monitoring circuitry further comprises:
for the at least one first type cell monitoring circuit, connecting the second switch to cause the active balancing and connecting the fourth switch to cause the latch balancing;
for the at least one second type cell monitoring circuit, connecting the third switch to cause the latch balancing; and
for the at least one third type cell monitoring circuit, connecting the first switch to cause the active balancing.

13. The method of claim 10, wherein the controlling of the cell monitoring circuitry comprises, based on an ignition device being activated, causing termination of latch balancing for the at least one first type cell monitoring circuit and the at least one second type cell monitoring circuit.

14. The method of claim 10, wherein the controlling of the cell monitoring circuitry comprises, based on an ignition device being activated, causing active balancing for the at least one first type cell monitoring circuit and the at least one third type cell monitoring circuit.

15. The method of claim 10, wherein the controlling of the cell monitoring circuitry comprises, based on an ignition device being deactivated, causing latch balancing for the at least one first type cell monitoring circuit and the at least one second type cell monitoring circuit.

16. The method of claim 10, wherein the controlling of the cell monitoring circuitry comprises, based on an ignition device being activated, causing termination of active balancing for the at least one first type cell monitoring circuit and the at least one third type cell monitoring circuit.

17. The method of claim 10, further comprising:
sending signals to configure:
the at least one first type cell monitoring circuit to directly wirelessly communicate with the battery management circuit;
the at least one second type cell monitoring circuit to relay wireless communications with the battery management circuit; and
the at least one third type cell monitoring circuit to wirelessly communicate with the battery management circuit via relayed wireless communications from the at least one second type cell monitoring circuit.

18. An method performed by a battery management system, the method comprising:
sending signals to configure:
at least one first cell monitoring circuit, of a cell monitoring circuitry of a battery comprising a plurality of cells, to directly wirelessly communicate with a battery management circuit of the battery management system;
at least one second cell monitoring circuit, of the cell monitoring circuitry, to relay wireless communications with the battery management circuit; and
at least one third cell monitoring circuit, of the cell monitoring circuitry, to wirelessly communicate with the battery management circuit via relayed wireless communications from the at least one second cell monitoring circuit;
receiving:
via a direct wireless communication with the battery management circuit, first status information of a battery module associated with the at least one first cell monitoring circuit;
via a relayed wireless communication with the battery management circuit, second status information of a battery module associated with the at least one second cell monitoring circuit; and
via a wireless communication relayed by the at least one second cell monitoring circuit to the battery management circuit, third status information of a battery module associated with the at least one third cell monitoring circuit; and
based on the first status information, second status information and third status information, controlling the cell monitoring circuitry to cause a reduction in one or more of:
a current consumption deviation between the at least one first cell monitoring circuit, the at least one second cell monitoring circuit, and the at least one third cell monitoring circuit; or
a dark current deviation between the at least one first cell monitoring circuit, the at least one second cell monitoring circuit, and the at least one third cell monitoring circuit.

19. The method of claim 18, wherein the sending the signals is based on determining that a wireless network comprising the cell monitoring circuitry is in an initial configuration state.

20. The method of claim 18, wherein the controlling of the cell monitoring circuitry comprises one or more of:
based on an ignition device being activated, causing termination of latch balancing for the at least one first cell monitoring circuit and the at least one second cell monitoring circuit;
based on the ignition device being activated, causing active balancing for the at least one first cell monitoring circuit and the at least one third cell monitoring circuit;
based on the ignition device being deactivated, causing latch balancing for the at least one first cell monitoring circuit and the at least one second cell monitoring circuit; or
based on the ignition device being activated, causing termination of active balancing for the at least one first cell monitoring circuit and the at least one third cell monitoring circuit.
